(19) United States
(12) Patent Application Publication
(10) Pub. No.: US 2026/0143581 A1
(43) Pub. Date: May 21, 2026

(54) HEAT DISSIPATION MODULE AND ELECTRONIC DEVICE COMPRISING SAME

(71) Applicant: Samsung Electronics Co., Ltd., Suwon-si (KR)

(72) Inventors: Jongdo PARK, Suwon-si (KR); Bitna KIM, Suwon-si (KR); Junghoon KIM, Suwon-si (KR)

(21) Appl. No.: 19/447,480

(22) Filed: Jan. 13, 2026

Related U.S. Application Data
(63) Continuation of application No. PCT/KR2024/009621, filed on Jul. 8, 2024.

(30) Foreign Application Priority Data
Jul. 20, 2023 (KR) 10-2023-0094920
Oct. 11, 2023 (KR) 10-2023-0135322

(51) Int. Cl. H05K 1/02; H05K 9/00

(52) U.S. Cl. CPC H05K 1/0203; H05K 9/0024

(57) ABSTRACT

An electronic device is provided. The electronic device includes a housing including a metal plate, a printed circuit board disposed inside the housing and including a heat source, and a heat dissipation structure disposed between the metal plate and the printed circuit board, wherein the heat dissipation structure includes a heat dissipation member, and a first heat transfer member disposed on the heat dissipation member, and wherein the first heat transfer member includes a first portion configured to transfer heat generated from the heat source and a second portion including an adhesive surface.

### CROSS-REFERENCE TO RELATED APPLICATION(S

This application is a continuation application, claiming priority under 35 U.S.C. § 365(c), of an International application No. PCT/KR2024/009621, filed on July 8, 2024, which is based on and claims the benefit of a Korean patent application number 10-2023-0094920, filed on July 20, 2023, in the Korean Intellectual Property Office, and of a Korean patent application number 10-2023-0135322, filed on October 11, 2023, in the Korean Intellectual Property Office, the disclosure of each of which is incorporated by reference herein in its entirety.

### BACKGROUND

### 1. Field

The disclosure relates to a heat dissipation module and an electronic device including the same.

### 2. Description of Related Art

Due to the remarkable advancements in information and communication technology and semiconductor technology, the proliferation and use of various electronic devices are rapidly increasing. Recent electronic devices, in particular, are being developed to be portable and capable of communication.

Electronic devices may refer to devices that perform specific functions based on built-in programs, such as home appliances, electronic organizers, portable multimedia players, mobile communication terminals, tablet PCs, audio/video devices, desktop/laptop computers, or car navigation systems. For example, these electronic devices may output stored information as audio or video. With the increasing integration of electronic devices and the widespread adoption of high-speed and high-capacity wireless communications, a single electronic device, such as a mobile communication terminal may now integrate multiple functions. For example, a single electronic device is integrating, in addition to communication functions, entertainment functions such as gaming, multimedia functions such as music/video playback, communication and security functions for mobile banking, calendar management, or even electronic wallets. Such electronic devices are being miniaturized to allow users to conveniently carry them.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide a heat dissipation module and an electronic device including the same.

Additional aspects will be set forth in part in the description which follows and, in part, will be apparent from the description, or may be learned by practice of the presented embodiments.

In accordance with an aspect of the disclosure, an electronic device is provided. The electronic device includes a housing including a metal plate, a printed circuit board disposed inside the housing and including a heat source, and a heat dissipation structure disposed between the metal plate and the printed circuit board, wherein the heat dissipation structure includes a heat dissipation member and a first heat transfer member disposed on the heat dissipation member, and wherein the first heat transfer member includes a first portion configured to transfer heat generated from the heat source and a second portion including an adhesive surface.

In accordance with another aspect of the disclosure, an electronic device is provided. The electronic device includes a housing including a metal plate, a printed circuit board disposed inside the housing and including a heat source, and a heat dissipation structure disposed between the metal plate and the printed circuit board. The heat dissipation structure includes a heat dissipation member disposed on the metal plate, and a first heat transfer member disposed on the heat dissipation member. The first heat transfer member includes a first portion configured to transfer heat generated from the heat source and a second portion disposed at the lower side of the first portion and including an adhesive surface.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram of an electronic device in a network environment according to an embodiment of the disclosure;

FIG. 2 is a perspective view illustrating the front face of an electronic device according to an embodiment of the disclosure;

FIG. 3 is a perspective view illustrating the rear face of the electronic device illustrated in FIG. 3 according to an embodiment of the disclosure;

FIG. 4A is an exploded perspective view illustrating the front face of the electronic device illustrated in FIG. 2 according to an embodiment of the disclosure;

FIG. 4B is an exploded perspective view illustrating the rear face of the electronic device illustrated in FIG. 2 according to an embodiment of the disclosure;

FIGS. 5 and 6 are cross-sectional views schematically illustrating a heat dissipation structure according to various embodiments of the disclosure;

FIG. 7 is a cross-sectional view schematically illustrating a heat dissipation structure according to an embodiment of the disclosure; and

FIG. 8 is a cross-sectional view schematically illustrating a heat dissipation structure including a cooling structure according to an embodiment of the disclosure.

Throughout the drawings, it should be noted that like reference numbers are used to depict the same or similar elements, features, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a wireless fidelity (Wi-Fi) chip, a Bluetooth^{®} chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

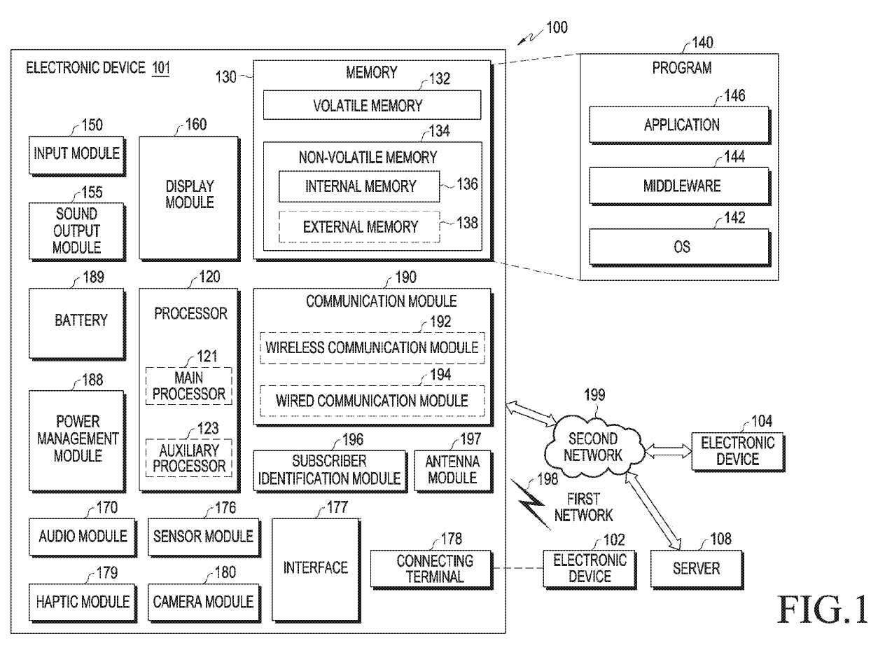

FIG. 1 is a block diagram illustrating an electronic device 101 in a network environment 100 according to an embodiment of the disclosure.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to one embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to one embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth^{TM}, wireless-fidelity (Wi-Fi) direct, or infrared data association (IrDA)) or the second network 199 (e.g., a long-range communication network, such as a legacy cellular network, a fifth generation (5G) network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a fourth generation (4G) network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the millimeter wave (mmWave) band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20Gbps or more) for implementing eMBB, loss coverage (e.g., 164dB or less) for implementing mMTC, or U-plane latency (e.g., 0.5ms or less for each of downlink (DL) and uplink (UL), or a round trip of 1ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102 or 104 or server 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

The electronic device according to an embodiment may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. As used herein, each of such phrases as "A or B," "at least one of A and B," "at least one of A or B," "A, B, or C," "at least one of A, B, and C," and "at least one of A, B, or C," may include any one of, or all possible combinations of the items enumerated together in a corresponding one of the phrases. As used herein, such terms as "1st" and "2nd," or "first" and "second" may be used to simply distinguish a corresponding component from another, and does not limit the components in other aspect (e.g., importance or order). It is to be understood that if an element (e.g., a first element) is referred to, with or without the term "operatively" or "communicatively," as "coupled with," "coupled to," "connected with," or "connected to" another element (e.g., a second element), it means that the element may be coupled with the other element directly (e.g., wiredly), wirelessly, or via a third element.

As used in connection with an embodiment of the disclosure, the term "module" may include a unit implemented in hardware, software, or firmware, and may interchangeably be used with other terms, for example, "logic," "logic block," "part," or "circuitry." A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term "non-transitory" simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to an embodiment of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore^{TM}), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to an embodiment, each component (e.g., a module or a program) of the above-described components may include a single entity or multiple entities, and some of the multiple entities may be separately disposed in different components. According to an embodiment, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

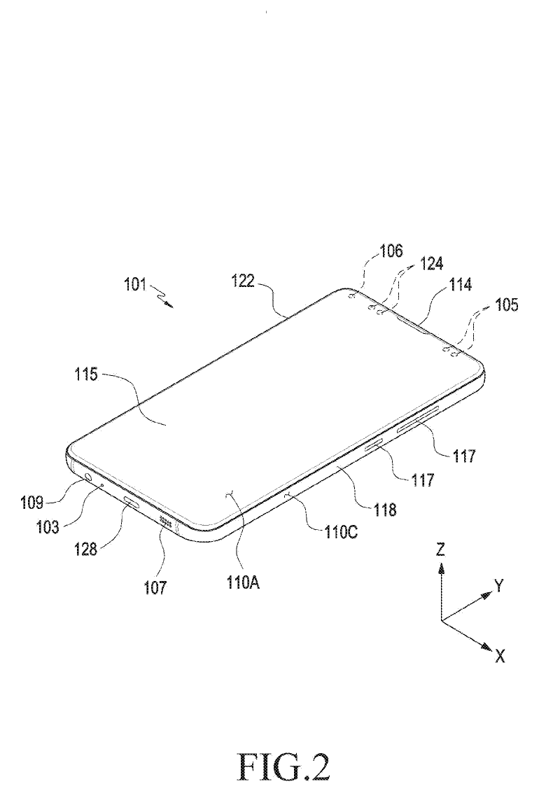

FIG. 2 is a perspective view illustrating the front face of an electronic device 101 according to an embodiment of the disclosure.

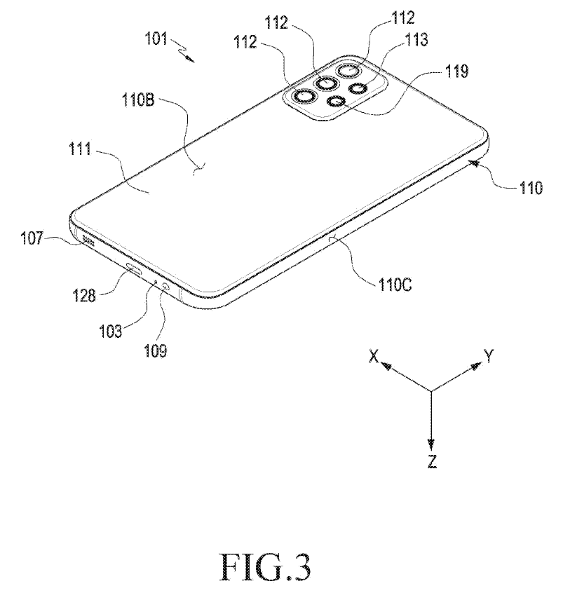

FIG. 3 is a perspective view illustrating the rear face of the electronic device 101 illustrated in FIG. 2 according to an embodiment of the disclosure.

Referring to FIGS. 2 and 3, an electronic device 101 (e.g., the electronic device 101 in FIG. 1) according to an embodiment may include a housing 110 including a first surface (or front surface) 110A, a second surface (or rear surface) 110B, and a lateral surface 110C enclosing a space between the first surface 110A and the second surface 110B. In an embodiment (not shown), the housing 110 may also refer to a structure forming a part of the first surface 110A in FIG. 2, the second surface 110B in FIG. 3, and the lateral surface 110C.

In an embodiment, the first surface 110A may be configured as a front plate 122 (e.g., a glass plate including various coating layers or polymer plate) having at least a portion that is substantially transparent. The second surface 110B may be configured as a substantially opaque rear plate 111. The rear plate 111 may be formed of, for example, coated or tinted glass, ceramic, polymer, metal (e.g., aluminum, stainless steel (STS), or magnesium), or a combination of at least two of these materials. The side surface 110C may be formed in a lateral structure (or "lateral bezel structure") 118 that is coupled to the front plate 122 and the rear plate 111 and includes metal and/or polymer. In an embodiment, the rear plate 111 and the lateral structure 118 may be integrally formed, and may include the same material (e.g., metal material such as aluminum).

According to an embodiment, the front plate 122 may include regions that curve from at least a portion of its edge toward the rear plate 111 to extend seamlessly. For example, the front plate 122 (or the rear plate 111) may include only one of the regions extending and curving toward the rear plate 111 (or the front plate 122) on one edge of the first surface 110A. According to an embodiment, the front plate 122 or the rear plate 111 may be a substantially flat plate and may not include, for example, a curved region. When the front plate 122 or the rear plate 111 includes a curved region, the thickness of the electronic device 101 in the portion including the curved region may be smaller than that of other portions.

According to an embodiment, the electronic device 101 may include at least one of a display 115, an audio module (e.g., a microphone hole 103, an external speaker hole 107, or a call receiver hole 114), a sensor module (e.g., a first sensor module 124, a second sensor module (not shown), or a third sensor module 119), a camera module (e.g., a first camera device 105, a second camera device 112, or a flash 113), a key input device 117, a light-emitting element 106, and a connector hole (e.g., a first connector hole 128 or a second connector hole 109). In an embodiment, the electronic device 101 may exclude at least one (e.g., the key input device 117 or the light-emitting element 106) of the components or may further include other components.

The display 115 may output a screen or be visually exposed, for example, through a significant portion of the first surface 110A (e.g., the front plate 122). In an embodiment, at least a portion of the display 115 may be visually exposed through the front plate 122 forming the first surface 110A or through a portion of the lateral surface 110C. In an embodiment, the edge of the display 115 may be formed to be substantially identical to the adjacent outer shape of the front plate 122. In an embodiment (not shown), the gap between the outer edge of the display 115 and the outer edge of the front plate 122 may be formed to be substantially the same in order to expand the area where the display 115 is visually exposed.

According to an embodiment, a recess or opening may be formed in a portion of a screen display area of the display 115, and at least one of an audio module (e.g., a call receiver hole 114), a sensor module (e.g., a first sensor module 124), a camera module (e.g., a first camera device 105), and a light-emitting element 106, which are aligned with the recess or opening, may be included. In an embodiment (not shown), at least one of an audio module (e.g., a call receiver hole 114), a sensor module (e.g., a first sensor module 124), a camera module (e.g., a first camera device 105), a fingerprint sensor (not shown), and a light-emitting element 106, which are disposed on the rear surface of the screen display area of the display 115, may be included. In an embodiment (not shown), the display 115 may be connected to or disposed adjacent to a touch detection circuit, a pressure sensor capable of measuring the intensity (pressure) of a touch, and/or a digitizer capable of detecting a magnetic stylus pen.

According to an embodiment, the audio modules 103, 107, and 114 may include a microphone hole 103 and a speaker hole (e.g., an external speaker hole 107 and a call receiver hole 114). The microphone hole 103 may have a microphone disposed therein for capturing external sound, and in an embodiment, a plurality of microphones may be provided to detect the direction of the sound. The speaker hole may include an external speaker hole 107 and a call receiver hole 114. In an embodiment, the speaker hole (e.g., the external speaker hole 107 or the call receiver hole 114) and the microphone hole 103 may be implemented as a single hole, or a speaker (e.g., a piezo speaker) may be included without a speaker hole (e.g., the external speaker hole 107 or the call receiver hole 114).

According to an embodiment, the sensor module may generate an electrical signal or data value corresponding to an internal operating state of the electronic device 101 or an external environmental state. The sensor module may include, for example, a first sensor module 124 (e.g., a proximity sensor) and/or a second sensor module (not shown) (e.g., a fingerprint sensor) disposed on the first surface 110A of the housing 110 and/or a third sensor module 119 disposed on the second surface 110B of the housing 110. The second sensor module (not shown) (e.g., a fingerprint sensor) may be disposed not only on the first surface 110A (e.g., the display 115) of the housing 110, but also on the second surface 110B or lateral surface 110C. The electronic device 101 may further include, for example, at least one of a gesture sensor, a gyro sensor, a barometric sensor, a magnetic sensor, an acceleration sensor, a grip sensor, a color sensor, an infrared (IR) sensor, a biometric sensor, a temperature sensor, a humidity sensor, or an illuminance sensor 124.

According to an embodiment, the camera module may include a first camera device 105 disposed on the first surface 110A of the electronic device 101, a second camera device 112 disposed on the second surface 110B, and/or a flash 113. The camera devices (e.g., the first camera device 105 and the second camera device 112) may include one or more lenses, image sensors, and/or image signal processors. The flash 113 may include, for example, a light-emitting diode or a xenon lamp. In an embodiment, one or more lenses (an infrared camera, a wide-angle lens, and a telephoto lens) and image sensors may be arranged on one surface of the electronic device 101. In an embodiment, the flash 113 may emit infrared light, and infrared light emitted by the flash 113 and reflected by a subject may be received through the third sensor module 119. The electronic device 101 or a processor (e.g., the processor 120 in FIG. 1) of the electronic device 101 may detect depth information of the subject, based on the time when the infrared light is received by the third sensor module 119.

According to an embodiment, the key input device 117 may be disposed on the lateral surface 110C of the housing 110. In an embodiment, the electronic device 101 may exclude a part or all of the key input devices 117, and the excluded key input device 117 may be implemented in other forms, such as soft keys, on the display 115. In an embodiment, the key input device may include a sensor module disposed on the second surface 110B of the housing 110.

According to an embodiment, the light-emitting element 106 may be disposed, for example, on the first surface 110A of the housing 110. The light-emitting element 106 may provide, for example, state information of the electronic device 101 in the form of light. In an embodiment, the light-emitting element 106 may provide, for example, a light source that is linked to the operation of the camera module (e.g., the first camera device 105). The light-emitting element 106 may include, for example, an LED, an IR LED, and a xenon lamp.

According to an embodiment, the connector holes (e.g., the first connector hole 128 and the second connector hole 109) may include a first connector hole 128 capable of accommodating a connector (e.g., a USB connector) for transmitting and receiving power and/or data to and from an external electronic device (e.g., the electronic device 102 in FIG. 1), and/or a second connector hole (e.g., an earphone jack) 109 capable of accommodating a connector for transmitting and receiving audio signals to and from the external electronic device.

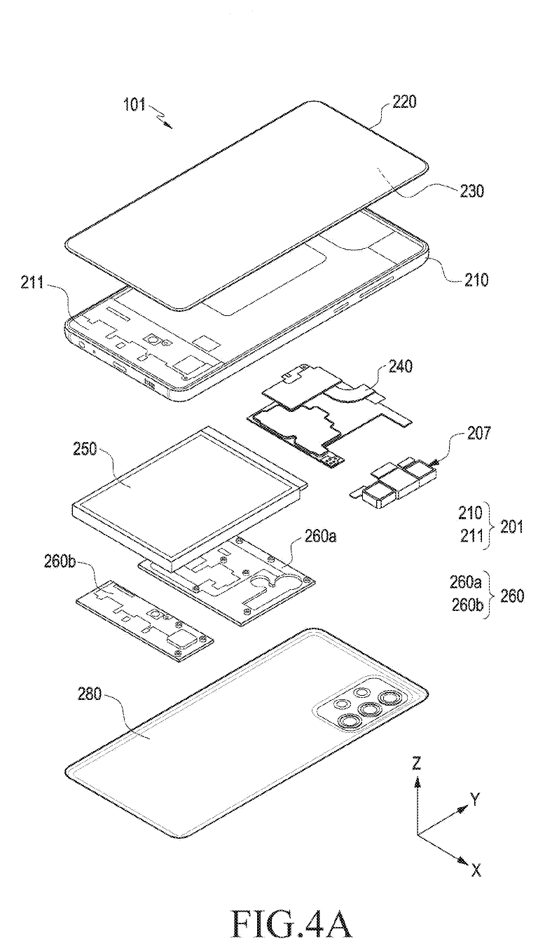

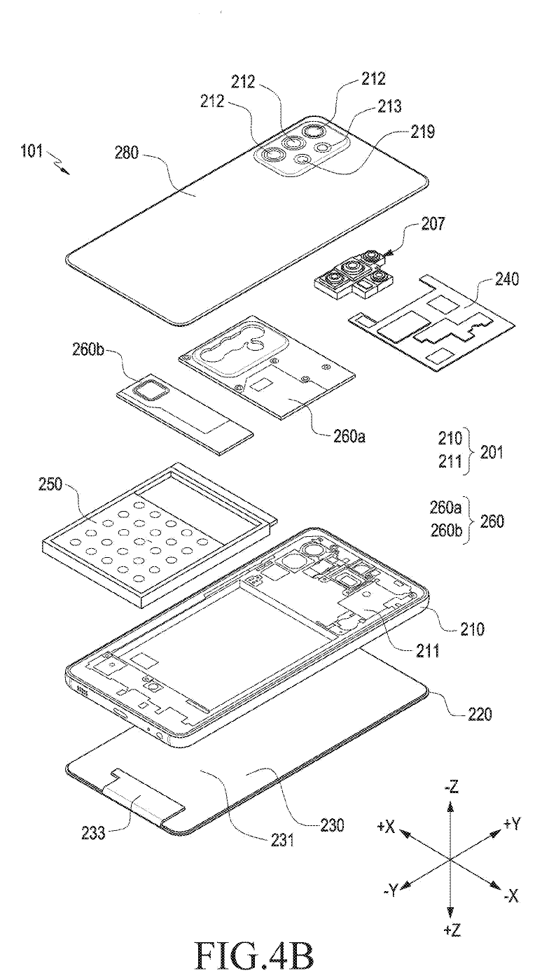

FIG. 4A is an exploded perspective view illustrating the front face of an electronic device as illustrated in FIG. 2 according to an embodiment of the disclosure.

FIG. 4B is an exploded perspective view illustrating the rear face of an electronic device as illustrated in FIG. 2 according to an embodiment of the disclosure.

Referring to FIGS. 4A and 4B, an electronic device 101 (e.g., the electronic device 101 in FIGS. 1, 2, or 3) may include a lateral structure 210, a first support member 211 (e.g., a bracket), a front plate 220 (e.g., the front plate 122 in FIG. 2), a display 230 (e.g., the display 115 in FIGS. 2 and 3), a printed circuit board (or substrate assembly) 240, a battery 250, a second support member 260 (e.g., a rear case), an antenna, a camera assembly 207, and a rear plate 280 (e.g., the rear plate 111 in FIG. 3).

In an embodiment, the electronic device 101 may exclude at least one (e.g., the first support member 211 or the second support member 260) of the components or may further include other components. At least one of the components of the electronic device 101 may be identical or similar to at least one of the components of the electronic device 101 in FIGS. 2 or 3, and redundant descriptions thereof will be omitted below.

According to an embodiment, the first support member 211 may be disposed within the electronic device 101 and connected to the lateral structure 210, or may be formed integrally with the lateral structure 210. The first support member 211 may be formed of, for example, a metal material and/or a non-metal material (e.g., polymer). When formed at least partially of a metal material, a portion of the lateral structure 210 or the first support member 211 may function as an antenna. The first support member 211 may have a display 230 coupled to one surface and a printed circuit board 240 coupled to the other surface. The printed circuit board 240 may have a processor (e.g., the processor 120 in FIG. 1), memory (e.g., the memory 130 in FIG. 1), and/or an interface (e.g., the interface 177 in FIG. 1) mounted thereon. The processor may include, for example, one or more of a central processing unit, an application processor, a graphics processing unit, an image signal processor, a sensor hub processor, or a communication processor.

According to an embodiment, the first support member 211 and the lateral structure 210 may be combined and referred to as a front case or housing 201. According to an embodiment, the housing 201 may be generally understood as a structure for accommodating, protecting, or arranging the printed circuit board 240 or the battery 250. In an embodiment, the housing 201 may be understood to include structures that may be visually or tactilely perceived by a user on the exterior of the electronic device 101, such as the lateral structure 210, the front plate 220, and/or the rear plate 280. In an embodiment, the "front surface or rear surface of the housing 201" may refer to the first surface 110A in FIG. 2 or the second surface 110B in FIG. 3. In an embodiment, the first support member 211 may be disposed between the front plate 220 (e.g., the first surface 110A in FIG. 2) and the rear plate 280 (e.g., the second surface 110B in FIG. 3), and may function as a structure for positioning electrical/electronic components, such as the printed circuit board 240 or the camera assembly 207.

In an embodiment, the display 230 may include a display panel 231 and a flexible printed circuit board 233 extending from the display panel 231. The flexible printed circuit board 233 may be understood to be, for example, at least partially disposed on the rear surface of the display panel 231 and electrically connected to the display panel 231. In an embodiment, reference numeral "231" may be understood to refer to a protective sheet disposed on the rear surface of the display panel. For example, unless otherwise specified in the following detailed description, the protective sheet may be understood to be part of the display panel 231. In an embodiment, the protective sheet may function as a buffer structure (e.g., a low-density elastomer such as a sponge) that absorbs external forces or an electromagnetic shielding structure (e.g., a copper (Cu) sheet). According to an embodiment, the display 230 may be disposed on the inner surface of the front plate 220 and may include a light-emitting layer to output a screen through at least a portion of the first surface 110A in FIG. 2 or the front plate 220. As mentioned above, the display 230 may output a screen through substantially the entire area of the first surface 110A in FIG. 2 or the front plate 220.

According to an embodiment, the memory may include, for example, volatile memory or non-volatile memory.

According to an embodiment, the interface may include, for example, a high-definition multimedia interface (HDMI), a universal serial bus (USB) interface, an SD card interface, and/or an audio interface. The interface may electrically or physically connect the electronic device 101 to an external electronic device, and may include, for example, a USB connector, an SD card/multimedia card (MMC) connector, or an audio connector.

According to an embodiment, the second support member 260 may include, for example, an upper support member 260a and a lower support member 260b. In an embodiment, the upper support member 260a may be arranged to surround the printed circuit board 240 together with a portion of the first support member 211. Circuit devices (e.g., processors, communication modules, or memories) implemented in the form of integrated circuit chips or various electrical/electronic components may be disposed on the printed circuit board 240. Depending on the embodiment, the printed circuit board 240 may be provided with an electromagnetic shielding environment by the upper support member 260a. In an embodiment, the lower support member 260b may be utilized as a structure capable of placing electrical/electronic components, such as a speaker module or interface (e.g., a USB connector, an SD card/MMC connector, or an audio connector). In an embodiment, electrical/electronic components, such as a speaker module or interface (e.g., a USB connector, an SD card/MMC connector, or an audio connector), may be placed on an additional printed circuit board (not shown). For example, the lower support member 260b may be disposed to surround the additional printed circuit board together with another portion of the first support member 211. A speaker module or interface disposed on the additional printed circuit board (not shown) or the lower support member 260b may be arranged to correspond to the audio module (e.g., the microphone hole 103 or the speaker hole (e.g., external speaker hole 107 or the call receiver hole 114)) or the connector hole (e.g., the first connector hole 128 or the second connector hole 109) in FIG. 2.

According to an embodiment, the battery 250 is a device for supplying power to at least one component of the electronic device 101, and may include, for example, a non-rechargeable primary battery, a rechargeable secondary battery, or a fuel cell. At least a part of the battery 250 may be disposed, for example, substantially on the same plane as the printed circuit board 240. The battery 250 may be disposed integrally within the electronic device 101, or may be disposed detachably from the electronic device 101.

Although not shown, the antenna may include a conductive pattern implemented on the surface of the second support member 260, for example, using a laser direct structuring process. In an embodiment, the antenna may include a printed circuit pattern formed on the surface of a thin film, and the thin film antenna may be disposed between the rear plate 280 and the battery 250. The antenna may include, for example, a near-field communication (NFC) antenna, a wireless charging antenna, and/or a magnetic secure transmission (MST) antenna. The antenna may enable short-range communication with an external device or wirelessly transmit and receive power required for charging. In an embodiment, another antenna structure may be formed by a portion or combination of the lateral structure 210 and/or the first support member 211.

According to an embodiment, the camera assembly 207 may include at least one camera module. The camera assembly 207 within the electronic device 101 may receive at least a portion of light incident through an optical hole or camera windows 212, 213, and 219. In an embodiment, the camera assembly 207 may be disposed on the first support member 211 adjacent to the printed circuit board 240. In an embodiment, the camera module(s) of the camera assembly 207 may be generally aligned with one of the camera windows 212, 213, and 219 and may be at least partially surrounded by the second support member 260 (e.g., the upper support member 260a).

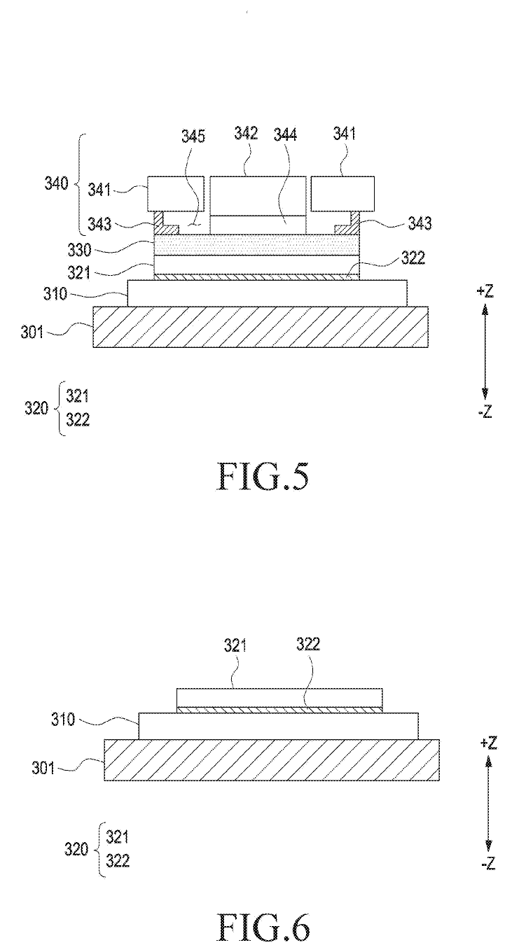

FIGS. 5 and 6 are cross-sectional views schematically illustrating a heat dissipation structure according to various embodiments of the disclosure.

Referring to FIGS. 5 and 6, an electronic device (e.g., the electronic device 101 in FIG. 2) may include a housing (e.g., the housing 110 in FIG. 2), a printed circuit board 340 disposed within the housing, and a heat dissipation structure. The configuration of the printed circuit board 340 in FIGS. 5 and 6 may be identical to all or part of the housing and printed circuit board 240 in FIGS. 4A and 4B. The structures shown in FIGS. 5 and 6 may be selectively combined with the structures shown in FIGS. 2, 3, 4A, and 4B.

According to an embodiment, the electronic device may include a housing, a printed circuit board 340 disposed within the housing, and a heat dissipation structure. According to an embodiment, the housing may include a metal plate 301. For example, the metal plate 301 may be a front plate (e.g., the front plate 220 in FIG. 2) and/or a rear plate (e.g., the rear plate 280 in FIG. 2).

According to an embodiment, the printed circuit board 340 may include a substrate 341, a heat source 342 in contact with the substrate 341, a shield can 343, and a second heat transfer member (TIM) 344.

According to an embodiment, the printed circuit board 340 may include a heat source 342. According to an embodiment, a plurality of electrical components may be disposed on at least one side of the circuit substrate 340. Some of the electrical components may be heat sources that generate heat. For example, the heat source 342 may be at least one chip disposed on at least one side of the substrate 341, and may include at least one of a power management integrated circuit (PMIC), a power amplifier (PAM), an application processor (AP), a communication processor (CP), a charger integrated circuit (Charger IC), and a DC converter. In this embodiment, the electrical component may be an application processor (AP) or a power management integrated circuit (PMIC).

According to an embodiment, the heat dissipation structure may be disposed between the metal plate 301 and the printed circuit board 340. According to an embodiment, the heat dissipation structure may include a heat dissipation member 310 (a first heat dissipation member) and a first heat transfer member 320 disposed on the heat dissipation member 310. According to an embodiment, the heat dissipation member 310 may be disposed on the metal plate 301. According to an embodiment, the heat dissipation member 310 may include the metal plate 301. For example, the metal plate 301 may itself be capable of dissipating heat. The heat dissipation member 310 and/or the metal plate 301 may receive heat generated from the heat source 342 through the first heat transfer member 320 and dissipate the heat.

According to an embodiment, the heat dissipation member 310 may dissipate heat generated from the heat source 342 of the printed circuit board 340. According to an embodiment, the heat dissipation member 310 may efficiently move the heat generated from the heat source 342 through the inside and dissipate it to the outside. The heat dissipation member 310 may be, for example, a graphite sheet. For example, the heat dissipation member 310 may include a water-cooled heat dissipation member, such as a heat pipe or a vapor chamber. A heat dissipation structure, such as a heat pipe or vapor chamber, may efficiently transfer heat through a continuous phase change in which a small amount of working fluid, which is injected into a sealed container and evacuated, vaporizes upon heat absorption and condenses upon heat release. Here, the material of the heat pipe, heat dissipation sheet, or heat dissipation paint may include a high-thermal conductivity material such as graphite, carbon nanotubes, natural renewable materials, silicon, and/or graphite. According to an embodiment, a carbon fiber TIM may include at least one of a liquid phase thermal interface material (TIM) and/or a solid phase thermal interface material (TIM). In various embodiments of the disclosure, the carbon fiber TIM may be formed of a solid phase thermal interface material (TIM). According to an embodiment, the heat dissipation member 310 that dissipates heat may be disposed in contact with the metal plate 301, thereby directly dissipating heat to the metal plate 301.

According to an embodiment, the heat dissipation member 310 may be formed of a material having a slippery surface of low friction. According to an embodiment, the heat dissipation member 310 may be formed of a material with low adhesive strength. The heat dissipation member 310 may have a surface that is difficult to process and may not easily allow attachment. According to an embodiment, for example, the thermal conductivity of the heat dissipation member 310 may be approximately 1000 W/mK or more.

According to an embodiment, the electronic device may include a first heat transfer member 320 disposed between the printed circuit board 340 and the heat dissipation member 310 to transfer heat generated from the printed circuit board 340 to the heat dissipation member 310, which is a heat dissipation structure. For example, the first heat transfer member 320 may be formed of a carbon fiber thermal interface material (TIM) capable of transferring heat generated from the heat source. According to an embodiment, the carbon fiber TIM may include at least one of a liquid phase thermal interface material (TIM) and/or a solid phase thermal interface material (TIM). However, the first heat transfer member 320 is not limited to carbon fiber TIM, and may include various heat dissipation materials or members for transferring heat generated from the heat source to the outside or the cover of the electronic device.

According to an embodiment, the first heat transfer member 320 may include a first portion 321 configured to transfer heat generated from the heat source 342, and a second portion 322 including an adhesive surface. According to an embodiment, the first heat transfer member 320 may include a first portion 321, and a second portion 322 laminated and bonded to the first portion 321. According to an embodiment, the first portion 321 may be formed integrally with the second portion 322. The first portion 321 may be, for example, a thermal interface material (TIM). The first portion 321 may include, for example, at least one of a liquid TIM, a nano TIM, a 3W TIM, and a 5W TIM. According to an embodiment, as the thermal conductivity of the first portion 321 increases, the adhesive strength decreases. Therefore, a high-performance first portion 321 may have low adhesive strength, making it difficult to attach to the heat dissipation member 310. According to an embodiment, the second portion 322 may include a heat dissipation tape. For example, the second portion 322 may include a heat conductive sheet and adhesive. For example, the second portion 322 may include a thermally conductive sheet and an adhesive. For example, the second portion 322 may be formed in the form of a thin film by dispersing and mixing a thermally conductive powder in a silicone resin and may include an adhesive on at least one surface. For example, the second portion 322 may include an adhesive on one or both surfaces of the thermally conductive sheet. According to an embodiment, the second portion 322 may be described as a heat dissipation tape or adhesive tape.

According to an embodiment, the second portion 322 of the first heat transfer member 320 may be disposed on the heat dissipation member 310, and the first portion 321 may be disposed on the second portion 322.

According to an embodiment, the thicknesses of the first portion 321 and the second portion 322 of the first heat transfer member 320 may be limited depending on the embodiment. When the second portion 322 is in contact with the first portion 321, heat transfer performance may be affected, so the thickness of the second portion 322 may be configured to be less than the thickness of the first portion 321. For example, the thickness of the first portion 321 may be approximately 30 times or more as thick as the thickness of the second portion 322.

According to an embodiment, the electronic device may further include a shielding film 330 between the first heat transfer member 320 and the printed circuit board 340. This may be intended to shield electromagnetic waves generated from the printed circuit board 340.

According to an embodiment, the printed circuit board may further include a substrate 341, at least one heat source 342 disposed on one surface of the substrate 341, a shield can 343 mounted on one surface of the substrate 341 to accommodate the heat source 342 and including at least one opening 345 formed in an area corresponding to the heat source 342, and a second heat transfer member (TIM) 344 disposed between the heat source 342 and the shielding film 330 while being in contact therewith. For example, the size of the first heat transfer member 320 may be greater than that of the second heat transfer member 344.

According to an embodiment, the shield can 343 may be formed to surround at least a portion of the heat source 342. According to an embodiment, the shield can 343 may have a structure in which, when the heat dissipation structure of the electronic device is viewed from above (e.g., when viewed from the +Z direction), an opening 345 is formed in an area where the heat source 342 and the shield can 343 at least partially overlap each other, for example, an area in which at least a portion of the heat source 342 that may come into contact with another material so that heat generated from the heat source 342 is released to the outside is located, or in a portion facing the heat source 342. The shield can 343 may be coupled to one side of the substrate 341 (e.g., the side facing the -Z direction). At this time, at least a portion of one side of the substrate 341 and the shield can 343 may be coupled by soldering. For example, the shield can 343 may include one side including the opening 345 and lateral surfaces forming a space between the one side and the substrate 341. The opening 345 may provide a movement path for heat generated from the heat source 342, and the shield can 343 may be manufactured in a shape (e.g., a closed rectangular loop) that surrounds at least a portion of the heat source 342.

According to an embodiment, the shielding film 330 may be disposed on at least a portion of the shield can 343 to close at least a portion of the opening 345. According to an embodiment, the shielding film 330 may include a shielding layer (not shown) and a support layer (not shown). The shielding film 330 may be disposed on one surface of the heat source 342 and may serve to prevent electromagnetic waves generated from the heat source 342 from affecting other electrical components (not shown) disposed within the electronic device.

According to various embodiments, the second heat transfer member 344 may be disposed such that at least a portion thereof is disposed within the opening 345 and at least one surface thereof is in contact with the shielding film 330. The second heat transfer member 344 may be disposed adjacent to the heat source 342 and may be formed of a thermal interface material (TIM) to effectively receive heat from the heat source 342. For example, the second heat transfer member 344 may be formed of a carbon fiber thermal interface material (TIM). However, the second heat transfer member 344 is not limited to the TIM and may include various heat dissipation materials or members for transferring heat generated from the heat source 342 to the heat dissipation member 310. For example, the various heat dissipation materials or members may include heat pipes, heat dissipation sheets, or heat dissipation paints. Here, the material of the heat pipe, heat dissipation sheet, or heat dissipation paint may include a high-thermal conductivity material such as graphite, carbon nanotubes, natural renewable materials, silicon, and/or graphite. According to an embodiment, a carbon fiber TIM may include at least one of a liquid phase thermal interface material (TIM) and/or a solid phase thermal interface material (TIM). In various embodiments of the disclosure, the carbon fiber TIM may be formed of a solid phase thermal interface material (TIM).

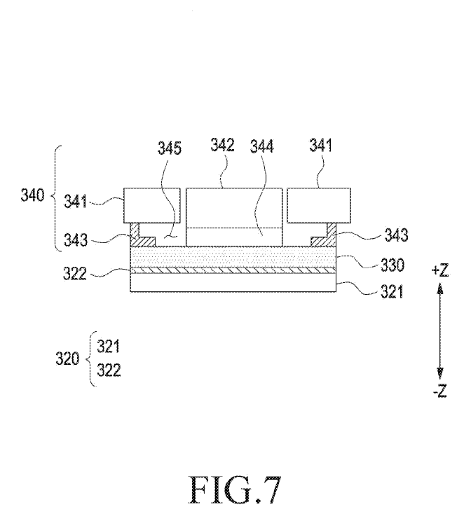

FIG. 7 is a cross-sectional view schematically illustrating a heat dissipation structure according to an embodiment of the disclosure.

Referring to FIG. 7, an electronic device (e.g., the electronic device 101 in FIG. 2) may include a housing (e.g., the housing 110 in FIG. 2), a printed circuit board 340 disposed within the housing, and a heat dissipation structure. The configuration shown in FIG. 7 may be identical to all or some of the configuration shown in FIGS. 5 and 6. The structure shown in FIG. 7 may be selectively combined with the structures shown in FIGS. 5 and 6.

According to an embodiment, the first heat transfer member 320 may include a first portion 321, and a second portion 322 laminated and bonded to the first portion 321. The first portion 321 may be, for example, a thermal interface material (TIM). The first portion 321 may include, for example, at least one of a liquid TIM, a nano TIM, a 3W TIM, and a 5W TIM. According to an embodiment, the higher the thermal conductivity of the first portion 321, the lower the adhesive strength. Therefore, a high-performance first portion 321 may have low adhesive strength, making it difficult to attach to the heat dissipation member 310.

According to an embodiment, the first portion 321 of the first heat transfer member 320 may be disposed on the heat dissipation member 310, and the second portion 322 may be disposed on the first portion 321. For example, the second portion 322 may attach the first portion 321 and the printed circuit board 340. For example, the second portion 322 may attach the first portion 321 and the shielding film 330. For example, the second portion 322 may attach the first portion 321 and the second heat transfer member 344. The stacking order of the first heat transfer member 320 may be implemented in various ways.

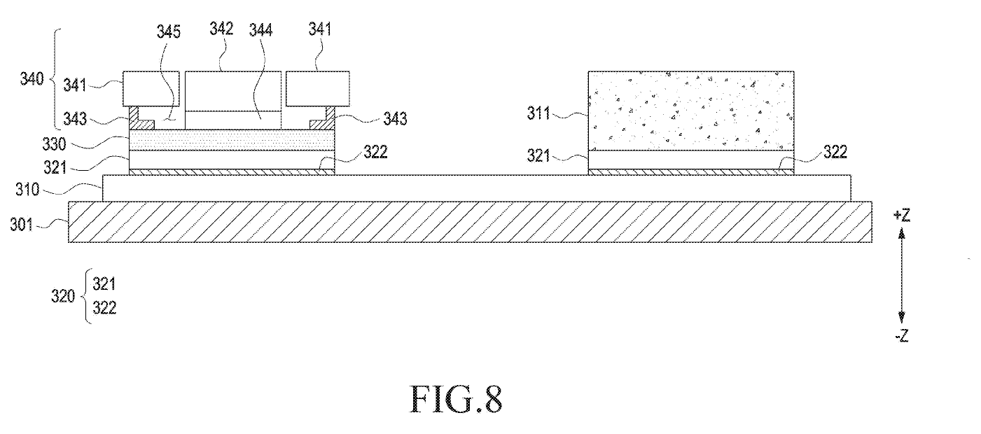

FIG. 8 is a cross-sectional view schematically illustrating a heat dissipation structure according to an embodiment of the disclosure.

Referring to FIG. 8, an electronic device (e.g., the electronic device 101 in FIG. 2) may include a housing (e.g., the housing 110 in FIG. 2), a printed circuit board 340 disposed within the housing, and a heat dissipation structure. The configuration shown in FIG. 8 may be identical to all or some of the configuration shown in FIGS. 5 and 6. The structure shown in FIG. 8 may be selectively combined with the structures shown in FIGS. 5 and 6.

According to an embodiment, the second heat dissipation member 311 may be formed of, for example, a cooling material. For example, it may include a cooler. For example, it may include a fan (e.g., an electric fan) that is attached to a component such as a radiator or a heat sink to forcibly discharge hot air.

According to an embodiment, a manufacturing process of an electronic device including a first heat transfer member 320 of the disclosure may include a first process of placing a heat dissipation member 310 on a metal plate 301, a second process of placing a first heat transfer member 320 in which a first portion 321 and a second portion 322 are bonded on the heat dissipation member 310, and a third process of placing a printed circuit board 340 on the first heat transfer member 320.

An electronic device according to an embodiment of the disclosure may include a housing including a metal plate, a printed circuit board disposed inside the housing and including a heat source, and a heat dissipation structure disposed between the metal plate and the printed circuit board. The heat dissipation structure may include a heat dissipation member and a first heat transfer member disposed on the heat dissipation member. The first heat transfer member may include a first portion 321 configured to transfer heat generated from the heat source and a second portion 322 including an adhesive surface.

According to an embodiment, the first portion and the second portion may be integrally formed.

According to an embodiment, the electronic device may further include a shielding film between the first heat transfer member and the printed circuit board.

According to an embodiment, the second portion may be disposed between the first portion and the heat dissipation member.

According to an embodiment, the second portion may be disposed between the first portion and the printed circuit board.

According to an embodiment, the heat dissipation member may include any one of a graphite sheet, a heat pipe, and a vapor chamber.

According to an embodiment, the printed circuit board may include a substrate, at least one heat source disposed on one surface of the substrate, a shield can mounted on one surface of the printed circuit board so as to accommodate the heat source and including at least one opening formed in an area corresponding to the heat source, and a second heat transfer member (TIM) disposed between the heat source and the shielding film while being in contact therewith.

According to an embodiment, a size of the first heat transfer member may be greater than a size of the second heat transfer member.

According to an embodiment, the first portion may be a thermal interface material (TIM).

According to an embodiment, the first portion may include any one of a liquid TIM, a nano TIM, a 3W TIM, and a 5W TIM.

According to an embodiment, a thickness of the first portion may be greater than a thickness of the second portion.

According to an embodiment, the thickness of the first portion may be 30 times or more as thick as the thickness of the second portion.

An electronic device according to an embodiment of the disclosure may include a housing including a metal plate, a printed circuit board disposed inside the housing and including a heat source, and a heat dissipation structure disposed between the metal plate and the printed circuit board. The heat dissipation structure may include a heat dissipation member 310 disposed on the metal plate, and a first heat transfer member 320 disposed on the heat dissipation member. The first heat transfer member may include a first portion 321 configured to transfer heat generated from the heat source and a second portion 322 disposed at the lower side of the first portion and including an adhesive surface.

According to an embodiment, the first heat transfer member may be configured such that the first portion and the second portion are laminated.

According to an embodiment, the electronic device may further include a shielding film between the first heat transfer member and the printed circuit board.

According to an embodiment, the heat dissipation member may be a graphite sheet.

According to an embodiment, the heat dissipation member may be a heat pipe.

According to an embodiment, the heat dissipation member may be a vapor chamber.

According to an embodiment, the first portion may be a thermal interface material (TIM).

According to an embodiment, the first portion may include any one of a liquid TIM, a nano TIM, a 3W TIM, and a 5W TIM.

The technical problems to be solved in this document are not limited to the technical problems mentioned above, and other technical problems not mentioned above will be clearly understood by those skilled in the art from the description below.

Generally, the first portion is easily damaged, so it may be structured to be protected inside a shield can, or an additional support member may be required. When the first portion is attached to a non-adhesive material, it may be easily delaminated and yield may be reduced, making it difficult to apply a high-performance heat dissipation structure.

An embodiment according to the disclosure includes a first heat transfer member in which a first portion (thermal interface material (TIM)) and a second portion joined together, thereby improving the productivity of the first heat transfer member.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. An electronic device comprising:
a housing comprising a metal plate;
a printed circuit board disposed within the housing; and
a heat dissipation structure disposed between the metal plate and the printed circuit board to transfer heat from the printed circuit board to the metal plate,
wherein the heat dissipation structure comprises:
a heat dissipation member disposed on the metal plate, and
a first heat transfer member disposed on the heat dissipation member, and
wherein the first heat transfer member comprises a first portion configured to transfer heat generated from the printed circuit board, and a second portion comprising an adhesive surface adhered to the heat dissipation member.

2. The electronic device of claim 1, wherein the first portion and the second portion are integrally formed.

3. The electronic device of claim 1, further comprising:
a shielding film between the first heat transfer member and the printed circuit board.

4. The electronic device of claim 1, wherein the second portion is disposed between the first portion and the heat dissipation member.

5. The electronic device of claim 1, wherein the second portion is disposed between the first portion and the printed circuit board.

6. The electronic device of claim 1, wherein the heat dissipation member comprises any one of a graphite sheet, a heat pipe, and a vapor chamber.

7. The electronic device of claim 3, wherein the printed circuit board comprises:
a substrate;
at least one heat source disposed on one surface of the substrate;
a shield can mounted on the one surface of the printed circuit board so as to accommodate the at least one heat source and comprising at least one opening formed in an area corresponding to the at least one heat source; and
a second heat transfer member disposed between the at least one heat source and the shielding film while being in contact therewith.

8. The electronic device of claim 7, wherein a size of the first heat transfer member is greater than a size of the second heat transfer member.

9. The electronic device of claim 1, wherein the first portion is a thermal interface material (TIM).

10. The electronic device of claim 1, wherein the first portion comprises any one of a liquid TIM, a nano TIM, a 3W TIM, and a 5W TIM.

11. The electronic device of claim 1, wherein a thickness of the first portion is greater than a thickness of the second portion.

12. The electronic device of claim 1, wherein a thickness of the first portion is 30 times or more as thick as a thickness of the second portion.

13. The electronic device of claim 1,
wherein the second portion of the first heat transfer member is disposed at a lower side of the first portion.

14. The electronic device of claim 1, wherein the first heat transfer member is configured such that the first portion and the second portion are laminated.

15. The electronic device of claim 7, wherein the at least one heat source comprises an integrated circuit mounted on the printed circuit board.
